(19) United States
(12) Patent Application Publication
(10) Pub. No.: US 2007/0269724 A1
(43) Pub. Date: Nov. 22, 2007

(54) METHOD AND PROCESS FOR IMMERSION EXPOSURE OF A SUBSTRATE

(75) Inventor: Torbjorn Sandstrom, Pixbo (SE)

Correspondence Address: HAYNES BEFFEL & WOLFELD LLP, P O BOX 366, HALF MOON BAY, CA, 94019, US

(73) Assignee: Micronic Laser Systems AB, Taby (SE)

(21) Appl. No.: 11/749,347

(22) Filed: May 16, 2007

Related U.S. Application Data
(60) Provisional application No. 60/747,460, filed on May 17, 2006.

(51) Int. Cl. G03F 1/00

(52) U.S. Cl. 430/5

(57) ABSTRACT

The technology disclosed relates to immersion lithography, in particular to the exposure of masks by deep and vacuum ultraviolet wavelengths with so-called sub-wavelength resolution. It also is likely to be useful for other methods of sub-wavelength lithography such as lithography on silicon wafers, surface-acoustic wave (SAW) and diffractive optical devices. In particular, it relates to controlling the contact angle between the immersion fluid and the top-most layer of the substrate, which is in contact with immersion fluid, by tuning the surface energy of the top-most layer and properties of the immersion fluid. It is useful to control this interface, in which issues such as entrainment of bubbles in the immersion fluid and puddles of fluid remaining after immersion have been encountered.

### RELATED APPLICATION

This application claims the priority to and the benefit of U.S. Provisional Application No. 60/747,460, filed 7 May 2006, with the title substantially the same as this application and naming as inventor (for U.S. purposes) Torbjorn Sandstrom. The provisional application is hereby incorporated by reference.

### BACKGROUND OF THE TECHNOLOGY

The technology disclosed relates to immersion lithography, in particular to the exposure of masks by deep and vacuum ultraviolet wavelengths with so-called sub-wavelength resolution. It also is likely to be useful for other methods of sub-wavelength lithography such as lithography on silicon wafers, surface-acoustic wave (SAW) and diffractive optical devices. In particular, it relates to controlling the contact angle between the immersion fluid and the top-most layer of the substrate, which is in contact with immersion fluid, by tuning the surface energy of the top-most layer and properties of the immersion fluid. It is useful to control this interface, in which issues such as entrainment of bubbles in the immersion fluid and puddles of fluid remaining after immersion have been encountered.

Immersion lithography is on its way from the lab into the semiconductor fabs. By adding an immersion fluid between the lens and the photoresist, the effective wavelength of the light is shortened by a factor of one divided by the refractive index of the fluid. Typically, the lens is surrounded by a trough of fluid and the stage is scanned under the stationary lens with fluid-filled trough. This assembly repeatedly wets and dries the surface. Ideally, the surface tension of the immersion liquid would pull the liquid away from the surface after the passage under the trough, leaving the surface dry and clean.

During the development of immersion technology for wafers, there have been problems with bubbles and drying marks. Air has been drawn in under the lens, presumably at the leading edge of the immersion assembly. Wet spots have formed on the workpiece surface after its passage under the immersion assembly, dried on the surface and created drying marks. Both bubbles and drying marks lead to defects and lower the yield of the process, which is undesirable.

Photomasks can be exposed in immersion in a fashion similar to wafers. The main difference is that the total exposure time is one to several hours for a photomask, whereas for a wafer it is less than one minute. This makes the exposure of photomasks two orders of magnitude more sensitive to leaching of the latent image into the immersion fluid, contamination of the resist from the fluid, and uptake of the fluid in the resist. All these concerns for wafer lithography become hurdles to mask writing in immersion. We disclose a process technology that addresses these concerns, including the problem of drying marks and bubbles, and the issue of degradation of the resist and image during long exposure times such as those in optical mask writing.

### SUMMARY OF THE TECHNOLOGY

The technology disclosed relates to immersion lithography, in particular to the exposure of masks by deep and vacuum ultraviolet wavelengths with so-called sub-wavelength resolution. It also is likely to be useful for other methods of sub-wavelength lithography such as lithography on silicon wafers, surface-acoustic wave (SAW) and diffractive optical devices. In particular, it relates to controlling the contact angle between the immersion fluid and the top-most layer of the substrate, which is in contact with immersion fluid, by tuning the surface energy of the top-most layer and properties of the immersion fluid. It is useful to control this interface, in which issues such as entrainment of bubbles in the immersion fluid and puddles of fluid remaining after immersion have been encountered. Particular aspects of this technology are described in the claims, specification and drawings.

### BRIEF DESCRIPTION OF THE DRAWINGS

FIG. 1 shows prior art.

FIG. 2 shows a preferred embodiment of a substrate used in the technology disclosed.

FIG. 3 illustrates surface contact of hydrophobic, hydrophilic and intermediate immersion liquids.

FIG. 4 shows a workpiece with a photoresist layer.

FIG. 5 the liquid is drawn out behind the lens and puddles.

FIG. 6 shows the case when the wetting of the surface changes due to the exposure.

FIG. 7 shows one aspect of the technology disclosed.

### DETAILED DESCRIPTION

The following detailed description is made with reference to the figures. Preferred embodiments are described to illustrate the present technology disclosed, not to limit its scope, which is defined by the claims. Those of ordinary skill in the art will recognize a variety of equivalent variations on the description that follows.

A surface layer with controlled surface energy, here called the wetting control layer, to give a near vertical contact angle to the immersion fluid (45-135 degrees, 60-120 degrees, or 75-105 degrees, depending in part on the relative movement speed of the workpiece and the immersion assembly). This reduces the likelihood of drawing air into the fluid and of leaving behind a puddle when the workpiece, as the workpiece moves. Contact angle is a well-known property of pairs of solid surfaces and liquids, and the selection of a material with a suitable contact angle to the fluid, typically water, is a task that a surface chemist can do. Examples of surface compositions and surface treatments that control the surface energy and contact angle are described in U.S. Pat. No. 7,119,035, which is incorporated by reference. A wide range of polymers with specific surface energy or wetting properties can be obtained from Polymer Source Inc, Dorval (Montreal), Canada.

Moreover, it is desirable that the wetting control layer dissolves in the developer. The developer mostly used is strongly alkaline and therefore a preferred embodiment of the wetting control layer is an alkaline-soluble layer with a contact angle to water in the range 45 to 135 degrees, in the range of 60 to 120 degrees, or the range of 75 to 105 degrees, depending in part on the speed at which the workpiece passes under the immersion assembly.

Another aspect of the technology disclosed aims to reduce the decay and degradation of the resist and image by prolonged contact with the immersion fluid, e.g. water or a water based mixture of liquids. In order to do so, the technology disclosed uses a non-chemically amplified resist in a pattern-transfer process (see U.S. Pat. No. 7,153,634, by the same inventor and incorporated by reference, for description of pattern transfer processes.) For pattern transfer, a thin non-amplified resist may be deposited on top of a typically opaque bottom layer that provides anti-reflective properties, planarization and etch resistance. The thin top resist is developed and used to form an etch mask for the subsequent unidirectional etching of the bottom layer. The bottom layer which typically is thicker, e.g. 300 nm, below a resist of typically 50-200 nm and preferably around 100 nm, acts as the etch mask for the patterned layer on the workpiece, e.g. chrome, MoSi, or shifter. The etch mask, here called the first etch mask, can be formed from the thin resist in several ways: by the resist containing silicon or similar etch-resistant substance, by absorbing silicon or similar after the development, or by being used to pattern a thin etch-resistant layer. The first etch mask may be used to mask the bottom layer to a directional oxygen or oxidizing etch. The second etch mask is formed by the etched bottom layer, which can be Novolac, by vertical oxidizing etching, e.g. RIE etching or oxygen plasma.

By using a non-amplified resist, the technology disclosed makes the process much more robust with respect to time, temperature and chemical action when subjected to the immersion fluid. For non-amplified resist, shelf-life is long, sensitivity to thickness variations is smaller, and sensitivity to soaking time, exposure time and to post-exposure bake conditions are all smaller. In contrast to the case with chemically amplified resists, a post exposure bake of non-amplified resists may not be needed at all, since the conversion of the resist from insoluble to soluble happens at the moment of illumination with actinic photons, without standing waves. The practical resolution is high, since the wet development is only used for the thin resist and there is no pattern collapse. Eliminating or reducing the post-exposure bake reduces loss of resolution due to diffusion. As a result, the resolution should only be limited by the molecular size of the resist. The penalty for using non-amplified resist is requiring a higher exposure dose. In a mask writer, which is not dose limited, this is not a problem.

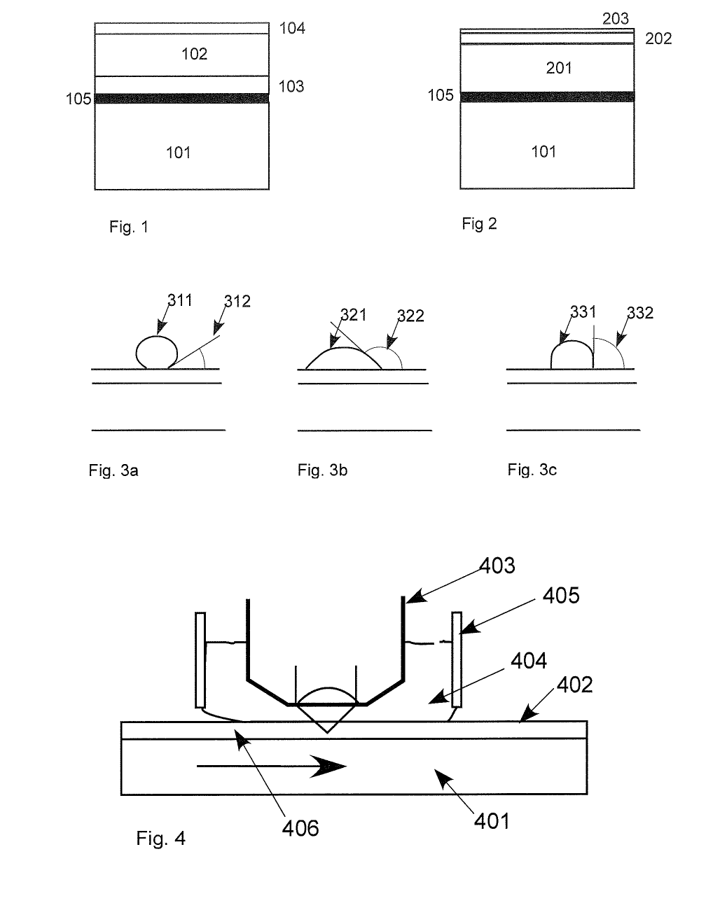

FIG. 1 shows a typical prior art workpiece (101) prepared with a layer to be patterned (105), a chemically amplified resist (102), a bottom anti-reflection coating (BARC) (103) and a top anti-reflection coating (TARC) (104).

FIG. 2 shows an embodiment of a substrate used in the technology disclosed: a workpiece (101) with a layer to be patterned (105), a bottom layer (201), a thin non-amplified resist (202), and a wetting-control layer (203).

A process embodiment of the technology disclosed begins with preparing the workpiece: 1. clean the substrate; 2. deposit the bottom layer and bake; 3. deposit the thin non-amplified resist and bake; 4. deposit the wetting control layer; and 5. put plates in storage. Using the workpiece may include the following steps: 1. remove the workpiece from storage; 2. expose it in an immersion exposure system; 3. develop the resist; 4. form the first etch mask, e.g. by gas phase silylation; 5. etch the bottom layer; and 6. use the bottom layer as second etch mask and etch the layer to be patterned.

FIG. 3 illustrates surface contact of hydrophobic, hydrophilic and intermediate immersion liquids. The hydrophobic liquid (311) in FIG. 3a has a contact angle (312) less than 90 degrees. The case in FIG. 3b is a hydrophilic liquid (321) which has a contact angle (322) of more than 90 degrees. The intermediate liquid (331) in FIG. 3c has a contact angle (332) of approximately 90 degrees.

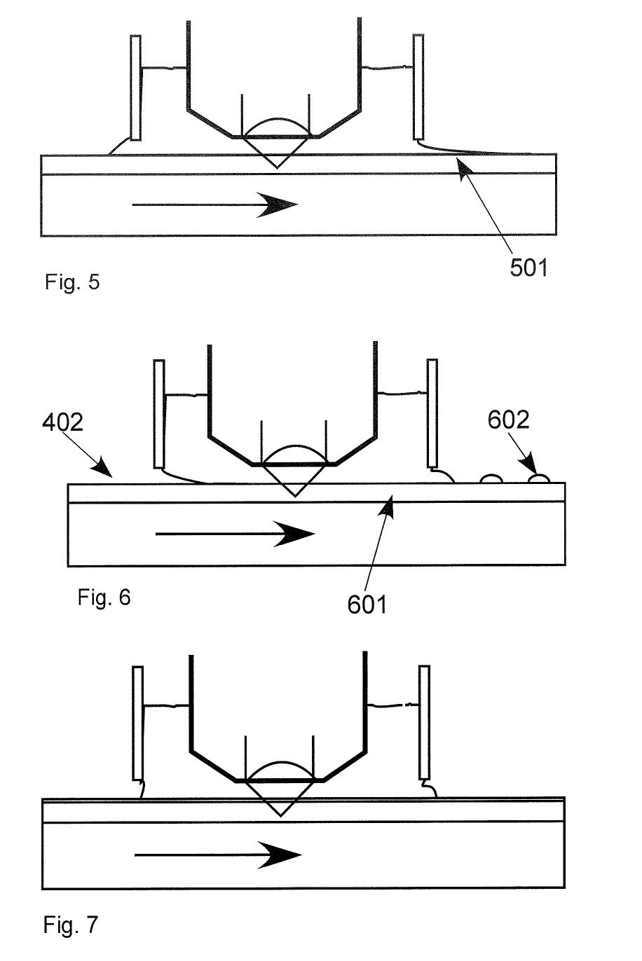

FIG. 4 shows a workpiece (401) with a photoresist (402), e.g. a photomask substrate or a wafer, being patterned by light in liquid immersion. The lens (403) focuses the images through the immersion liquid (404) which is confined to a puddle by a trough or container (405). Depending on the hydrophobicity of the surface, or, more generally, on the contact angle between the liquid and the photoresist, the liquid will be pulled in (406) under the trough as shown in FIG. 4 and/or may float out over the surface as in FIG. 5. When there is a scanning motion between the immersion assembly that wets the surface and the workpiece, the case in FIG. 4 creates a risk of air is being dragged in under the liquid and confined in the form of bubbles. In the wetting case in FIG. 5, the liquid is drawn out (501) behind the lens, forming and puddle and creating a risk of evaporative cooling and drying marks on the surface.

FIG. 6 shows how the wetting and contact angle at the surface can change due to exposure of the resist to the immersion fluid. Some resists, notably positive non-amplified resists, the resist changes from strongly non-wetting to wetting during the exposure. The same change, but smaller in magnitude, may happen also with chemically amplified resist. FIG. 6 shows how the exposed areas (601) are more wetting than the unexposed ones and result in droplets or puddles of immersion liquid (602) on the surface after the immersion assembly has passed.

FIG. 7 shows the surface of the photoresist (402) treated with a thin wetting control layer 203 to give a controlled surface energy that does not change with the exposure. The contact angle of the wetting control layer is near vertical (45-135 degrees, 60-120 degrees or 75-105 degrees,) giving a well-defined edge of the immersion fluid under the immersion assembly and reducing the risk of bubbles and drying marks. The benefit of the extra layer to control and lock the surface energy is particularly high when the photoresist is non-amplified. FIG. 7 shows no formation of droplets on the surface due to the insensitivity of the top layer to the exposing light, in contrast to FIG. 6. Compared to FIGS. 4 and 5, FIG. 7 also shows better control of the puddle with less risk of bubbles and drying marks.

The surface control layer can be one or many molecules thick. It can be deposited by dipping, spraying, spinning, evaporation, sputtering, or by a chemical gas or liquid treatment of the surface of the resist. There may be additional layers between the resist and the wetting control layer.

The exposing vacuum wavelength is 248, 193, 157, 257, 266, 308 or another wavelength in the range 150 to 310 nm.

### Particular Embodiments

One embodiment is a method for patterning a workpiece, such as a photomask or a wafer. This method includes providing a workpiece with substrate, a base layer over the substrate, a non-amplified resist layer over the base layer and a wetting control layer over the non-amplified resist layer. The method further includes exposing the resist layer through an immersion fluid and developing the resist, forming a first etch mask. It includes etching the base layer to form a second etch mask and etching through the second etch mask to pattern the workpiece.

In one variation on this embodiment, the wetting control layer has a contact angle versus the immersion fluid in the range 45 to 135 degrees. In another variation, the wetting control layer has a contact angle versus the immersion fluid in the range 60 to 120 degrees. In yet another variation, the wetting control layer has a contact angle versus the immersion fluid in the range 75 to 105 degrees.

One aspect of this method is that the exposing wavelength in vacuum may be in the range of 150-310 nm. More specifically, it may be chosen from the group 248, 193, 157, 257, 266 or 308 nm.

According to this method, the immersion fluid may be water. The thickness of the non-amplified resist may be in range 50-200 mn.

This method may be practiced with the developing the resist following the exposing the resist without a post-exposure bake step in between.

Optionally, the method may further include using the workpiece as a mask to expose a device substrate, patterning the device substrate and forming a feature of a device. These are conventional process steps that are well-understood.

Another embodiment is a substrate prepared for exposure, including a substrate, a base layer over the substrate, a non-amplified photoresist layer over the base layer, and a wetting control layer over the non-amplified photoresist layer.

Optionally, the base layer is essentially opaque to the exposing wavelength. The non-amplified photoresist layer may contain silicon.

An alternative device embodiment is a photomask produced by the process following process: providing a workpiece with substrate, a base layer over the substrate, a non-amplified resist layer over the base layer and a wetting control layer over the non-amplified resist layer; exposing the resist layer through an immersion fluid and developing the resist, forming a first etch mask; etching the base layer to form a second etch mask and etching through the second etch mask to pattern the workpiece. Following this process, the resulting photomask will be have the observable characteristics that the resolution is better than the wavelength of the exposing radiation and the resulting photomask is substantially free of defects caused by contact between the resist and immersion fluid, caused by entrainment of bubbles in the immersion fluid, or caused by drying marks.

While the present technology disclosed is disclosed by reference to the preferred embodiments and examples detailed above, it is understood that these examples are intended in an illustrative rather than in a limiting sense.

We claim as follows:

1. A method of printing a microlithographic pattern on a transparent substrate having A method for patterning a workpiece, such as a photomask, including:
providing a workpiece with substrate, a base layer over the substrate, a non-amplified resist layer over the base layer and a wetting control layer over the non-amplified resist layer;
exposing the resist layer through an immersion fluid;
developing the resist, forming a first etch mask;
etching the base layer to form a second etch mask; and
etching through the second etch mask to pattern the workpiece.

2. The method of claim 1, wherein the wetting control layer has a contact angle versus the immersion fluid in the range 45 to 135 degrees.

3. The method of claim 1, wherein the wetting control layer has a contact angle versus the immersion fluid in the range 60 to 120 degrees.

4. The method of claim 1, wherein the wetting control layer has a contact angle versus the immersion fluid in the range 75 to 105 degrees.

5. The method of claim 1, wherein exposing wavelength in vacuum is in the range of 150-310 nm.

6. The method of claim 1, wherein the exposing wavelength in vacuum is chosen from the group 248, 193, 157, 257, 266 or 308 nm.

7. The method of claim 1, wherein the immersion fluid is water.

8. The method of claim 1, wherein the thickness of the non-amplified resist is in range 50-200 nm.

9. The method of claim 1, wherein the developing the resist follow the exposing the resist without a post-exposure bake step.

10. The method of claim 1, further including using the workpiece as a mask to expose a device substrate, patterning the device substrate and forming a feature of a device.

11. A substrate prepared for exposure, including a substrate, a base layer over the substrate, a non-amplified photoresist layer over the base layer, and a wetting control layer over the non-amplified photoresist layer.

12. The substrate prepared for exposure of claim 11, wherein the base layer is essentially opaque to the exposing wavelength.

13. The substrate prepared for exposure of claim 11, wherein the non-amplified photoresist layer contains silicon.

14. A photomask produced by the process in claim 1.
